(19) United States
(12) Patent Application Publication
(10) Pub. No.: US 2025/0389756 A1
(43) Pub. Date: Dec. 25, 2025

(54) HALL SENSOR WITH MULTILEVEL PACKAGE SUBSTRATE

(71) Applicant: Texas Instruments Incorporated, Dallas, TX (US)

(72) Inventors: Ruby Ann Camenforte, Goleta, CA (US); Charmaine Grace Facal, Olongapo City (PH); Vincy Ann Danganan, Pampanga (PH)

(21) Appl. No.: 18/752,994

(22) Filed: Jun. 25, 2024

(51) Int. Cl. G01R 15/20

(52) U.S. Cl. CPC G01R 15/202

(57) ABSTRACT

An electronic device includes a multilevel package substrate having a top level and a bottom level, the top level including a conductive U-shaped trace, the bottom level including a conductive lead exposed along a side of the electronic device, a semiconductor die attached to the top level of the multilevel package substrate and having a Hall sensor positioned above the U-shaped trace, and a package structure that encloses a portion of the semiconductor die and a portion of the U-shaped trace.

### BACKGROUND

Hall sensors are used for current sensing in a variety of applications, such as providing current feedback signals in motor drives. Hall sensor packages using etched lead frames have design and performance limitations such as mold voiding issues with incomplete mold fill near a sensed current conductor of the lead frame, which can decrease voltage performance of the hall sensor. For example, a shaped turn feature can be used to generate a magnetic field for a Hall sensor, but the lead frame turn feature is difficult to fill during molding operations and prone to voiding after mold because air can get trapped. The features can be modified somewhat, but lead frames are two dimensional structures with limited ability to modify a layout design without significantly increasing the package size. Molding processes, design rules and materials can be changed to improve fill, but these adjustments are limited and cannot ensure void-free molding especially for compact package designs. Moreover, etched lead frames are restricted to one metal layer of wiring and lead frame-based packages are generally large as leads take up space and do not allow signal routing. Moreover, the lead frame package types do not provide isolation for interior terminals and cannot accommodate mounting of other components.

### SUMMARY

In one aspect, an electronic device includes a multilevel package substrate with top and bottom levels, a semiconductor die attached to the top level, and a package structure. The top level of the multilevel package substrate has a conductive U-shaped trace, and the bottom level has a conductive lead exposed along a side of the electronic device. The semiconductor die has a Hall sensor positioned above the U-shaped trace and the package structure encloses a portion of the semiconductor die and a portion of the U-shaped trace.

In another aspect, a system includes a circuit board having a conductive trace, and an electronic device. The electronic device includes a multilevel package substrate with top and bottom levels, a semiconductor die attached to the top level, and a package structure. The top level of the multilevel package substrate has a conductive U-shaped trace. The bottom level has a conductive lead exposed along a side of the electronic device and attached to the conductive trace of the circuit board. The semiconductor die has a Hall sensor positioned above the U-shaped trace and the package structure encloses a portion of the semiconductor die and a portion of the U-shaped trace.

In a further aspect, a method includes forming a conductive U-shaped trace in a top level of a multilevel package substrate, forming a conductive lead in a bottom level of the multilevel package substrate, attaching a semiconductor die to the top level of the multilevel package substrate with a Hall sensor positioned above the U-shaped trace, and molding a package structure that encloses the U-shaped trace.

### BRIEF DESCRIPTION OF THE DRAWINGS

FIG. 1 is a sectional side elevation view of an electronic device taken along line 1-1 in FIGS. 1A and 1B.

FIG. 1A is a sectional top view of the electronic device taken along line 1A-1A in FIG. 1.

FIG. 1B is a sectional top view of the electronic device taken along line 1B-1B in FIG. 1.

FIG. 2 is a flow diagram of a method of fabricating an electronic device.

FIGS. 3-13 are partial side elevation views of the electronic device of FIG. 1 undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material.

Unless otherwise stated, “about,” “approximately,” or “substantially” preceding a value means+/−10 percent of the stated value. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

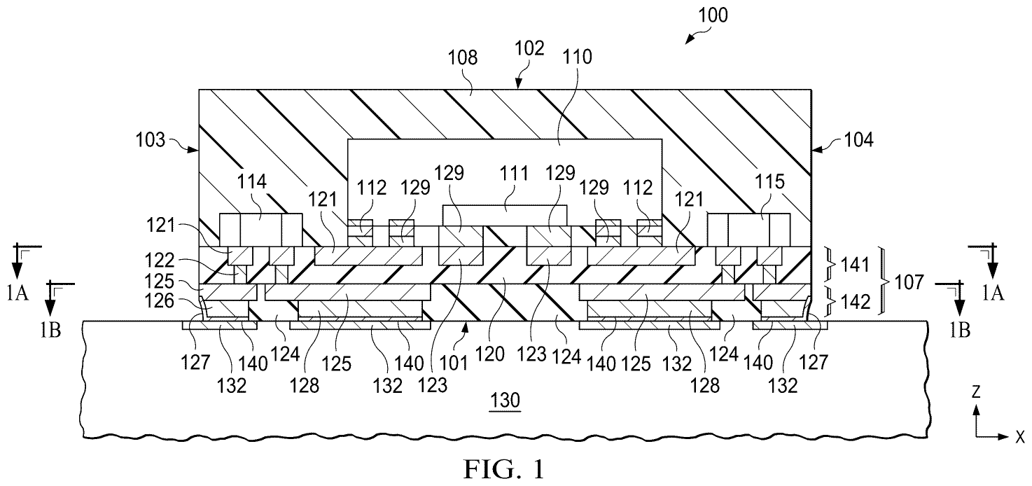

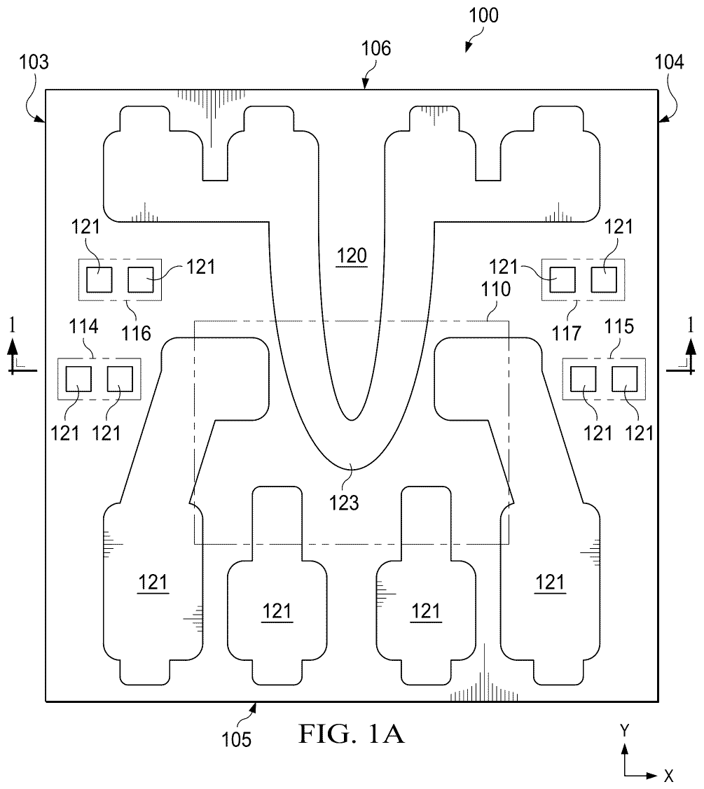

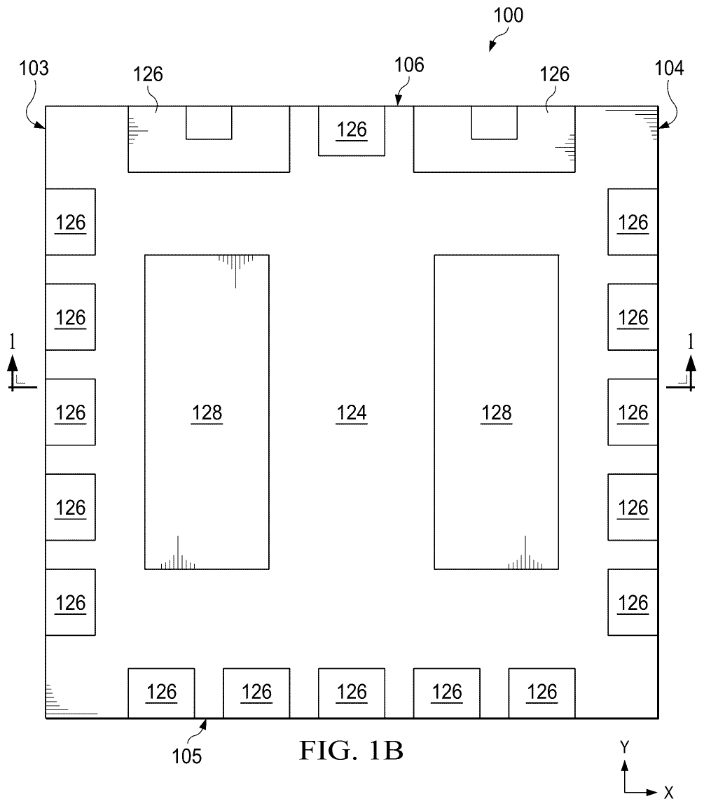

FIGS. 1-1B show a Hall sensor electronic device 100 including a die with a hall sensor above a top level U-shaped turn feature of a multilevel package substrate. The example electronic device 100 also has additional surface mount components, along with leads and isolated split pads of a bottom level of the multilevel package substrate. The electronic device 100 is illustrated in an example three-dimensional space with a first direction X, a perpendicular (orthogonal) second direction Y (FIGS. 1A and 1B), and a third direction Z (FIG. 1) that is perpendicular (orthogonal) to the respective first and second directions X and Y. Structures or features along any two of these directions are orthogonal to one another. As shown in FIG. 1, the electronic device 100 has opposite first and second sides 101 and 102 (e.g., bottom and top), respectively, which are spaced apart from one another along the third direction Z in the illustrated position. The electronic device 100 also has laterally opposite third and fourth sides 103 and 104 that are spaced apart from one another along the first direction X, and fifth and sixth sides 105 and 106 (FIGS. 1A and 1B) that are spaced apart from one another along the second direction Y in the illustrated position.

The electronic device 100 includes a multilevel package substrate 107 (FIG. 1) and a semiconductor die 110 with a Hall sensor 111. A package structure 108 encloses at least a portion of the semiconductor die 110. The semiconductor die 110 has conductive terminals 112, such as copper pillars extending downward from bond pads of the die 110. The electronic device 100 also includes surface mount components 114, 115, 116, and 117 (FIGS. 1 and 1A). As best shown in FIGS. 1 and 1A, the multilevel package substrate 107 has a first dielectric 120 with conductive metal first trace features 121 and conductive metal first via features 122, as well as a U-shaped trace 123 in a top level 141. In one example, the dielectric 120 is or includes magnetic material to facilitate operation of the hall sensor 111. In the illustrated example, the trace features 121 and 123, and the via features 122 are or include copper and are formed by electroplating as described further below. In other examples, different conductive metals can be used.

As shown in FIGS. 1 and 1B, the second level 142 of the multilevel package substrate 107 has a second dielectric 124 with conductive metal second trace features 125 and conductive metal second via features 126. The via features include conductive leads 126 that are exposed along the side 101 of the electronic device 100. The leads 126 in one example have indents 127 that extend into the bottom first side 101 and into lateral sides of one or more of the leads 126, for example, as shown in FIG. 1. The bottom level 142 in one example also includes conductive split pads 128 that are spaced apart from the conductive leads 126. The conductive split pads 128 in one example are electrically isolated from one another and from other conductive features and are exposed along the side 101 of the electronic device 100. In one example, the trace features 125, the via features and the leads 126 of the second level 142 are or include copper and are formed by electroplating. Given the illustrated example, the electronic device 100 includes raised studs 129 on the top level 141 of the multilevel package substrate 107. The raised studs 129 in one example provide extensions of the U-shaped trace 123 as shown in FIG. 1, and also provide extensions to which the conductive terminals 112 of the semiconductor die 110 are attached. In another example, the raised studs 129 can be omitted. In one example, the conductive leads 126 and the conductive split pads 128 have a plated surface 140 exposed along the first side 101 of the electronic device 100.

In the illustrated example, the conductive terminals 112 of the semiconductor die 110 are soldered to the raised studs 129 on the pads 121 of the top level 141 of the multilevel package substrate 107, for example, by flip chip soldering. The semiconductor die 110 is attached to the top level 141 of the multilevel package substrate 107 with the Hall sensor 111 positioned above the U-shaped trace 123. The package structure 108 in this example encloses a portion of the semiconductor die 110 and a portion of the U-shaped trace 123. In other implementations, the multilevel package substrate 107 can include further intermediate levels between the top level 141 and the bottom level 142.

The package structure 108 in one example includes a magnetic material, such as a magnetic mold compound with embedded magnetic particles in a molded plastic structure. In this or another example, the multilevel package substrate 107 includes a magnetic material. For example, the dielectric 120 can include magnetic material alone or in combination with a magnetic material molded package structure 108 to facilitate operation of the hall sensor 111. In other examples, magnetic structures are provided in the top or first level 141 as well as in other levels of a multilevel package substrate 107. Magnetic material surrounding or proximate to the U-shaped trace 123 and any included raised stud 129 on the U-shaped trace 123 can provide a magnetic field path to assist magnetic field sensing by the hall sensor 111 of the semiconductor die 110. In addition, further intermediate levels (not shown in FIGS. 1-1B) can be included to provide higher current carrying capability for the U-shaped trace 123, and further via and/or trace structures in the top level 141 and/or intermediate levels can be included to supplement the current carrying capability of the U-shaped trace 123 in a thicker U-shaped conductive metal structure that extends beyond the trace layer of the top level 141.

Moreover, magnetic material of the molded package structure 108 can be provided in the gap between the bottom side of the semiconductor die 110 and the top side of the multilevel package substrate 107 for magnetic coupling, alone or in combination with further magnetic material 120 of the top level 141 and/or intermediate levels (not shown) of the multilevel package substrate 107. The use of the multilevel package substrate 107 facilitates design flexibility regarding hall sensor performance while reducing overall device size and allowing inclusion of additional (e.g., service mark) components 114-117) and higher I/O count (e.g., device pin count) as well as the possibility of having interior isolated split pads 128.

As further shown in FIG. 1, the electronic device 100 can be installed in any suitable form of system, for example, for current sensing or other applications in which a hall sensor is beneficial. The system example of FIG. 1 includes a circuit board 130 with conductive traces 132 along a top side thereof. The leads 126 and the interior isolated split pads 128 along the first side 101 of the electronic device 100 are soldered to respective ones of the circuit board conductive traces 132. In another example, the electronic device 100 can be installed in a socket (not shown) of the circuit board 130 with the conductive leads 126 and the split pads 128 engaging corresponding conductive metal features of the socket to form electrical connections between the electronic device 100 and the circuit board 130. In either implementation, the inclusion of the surface mount components 114-117 within the packaged electronic device 100 facilitates reduction in overall circuit board space and system size. Moreover, the flexibility and signal routing capabilities of the multilevel package substrate 107 facilitates a higher number of device-to-circuit board electrical connections (e.g., higher I/O count) compared to lead frame-based hall sensor devices.

In addition, the provision of the dielectric layers 120 and 124 and the various levels 141 and 142 (and in any further included intermediate levels) facilitates complete void-free filling of magnetic material to engage the U-shaped trace 123 compared with lead frame-based designs. This mitigation or avoidance of magnetic material voids helps ensure reliable performance of the hall sensor 111 to sense magnetic fields generated by current flow through the U-shaped trace 123. The example molded magnetic package structure 108 encloses portions of the U-shaped trace 123 in the included raised stud 129 that extends along the top side of the U-shaped trace 123, as well as a portion of a semiconductor die 110 (FIG. 1). The molded magnetic package structure 108 in one example is generally rectangular and defines approximately planar top and lateral sides 102-106, although not a requirement of all possible implementations. The molded magnetic package structure 108 in one example is formed of magnetic molding compound, sometimes referred to as magnetic mold compound, which provides magnetic coupling for the field generated by current flow through the U-shaped trace 123 and the associated raised stud 129.

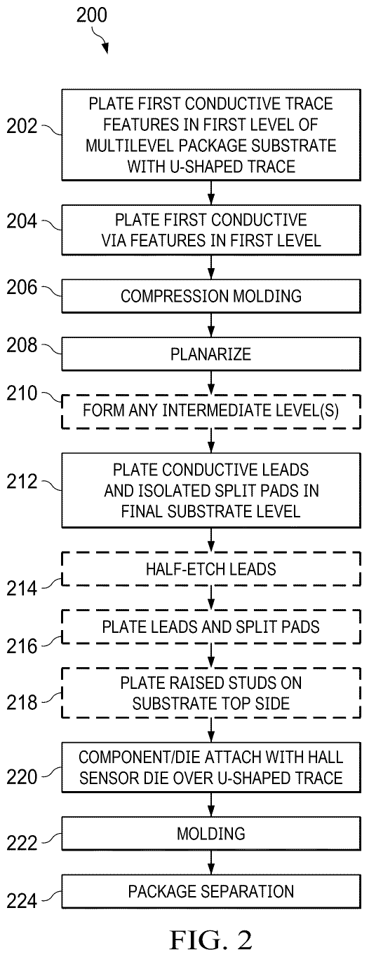

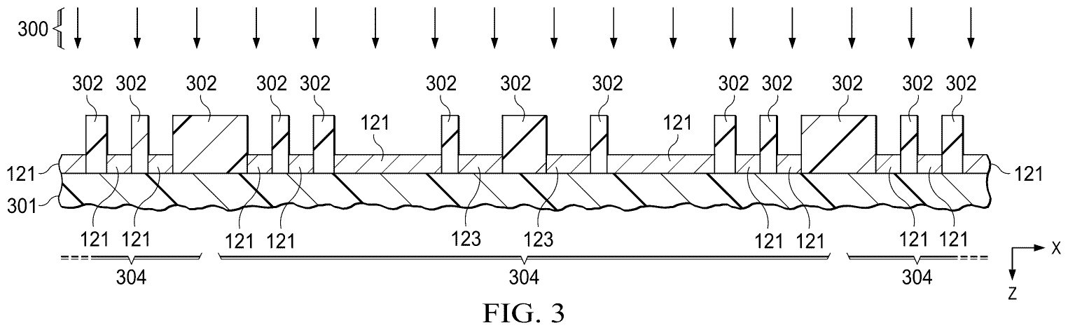

Referring now to FIGS. 2-13, FIG. 2 shows a method 200 of fabricating an electronic device and FIGS. 3-13 illustrate one example of the above described electronic device 100 undergoing fabrication processing according to one implementation of the method 200.

The method 200 includes fabrication of the multilevel package substrate 107 having two or more levels. The levels 141 and 142 in one example are built one at a time starting with deposition of a seed copper layer on a metal carrier, for example, using chemical vapor deposition. A first conductive trace layer is formed at 202 in FIG. 2, including patterned electroplating to form conductive copper trace features 121 in the first level 141 of the multilevel package substrate 107 described above, where the first trace features include a U-shaped trace. FIG. 3 shows one example, in which an electroplating process 300 is performed with a first plating mask 302 that deposits copper in the exposed areas of the mask 302 to form the copper metal trace features of the first trace of the first level 141 on the exposed portions of the copper seed layer on the top side of a carrier 301, including the U-shaped trace 123 (e.g., FIGS. 1 and 1A above) and other first conductive trace features 121. The illustrated process is performed in a panel array with rows and columns of unit areas 304, and the drawing show a portion of the panel array structure including a center unit area 304 and portions of laterally adjacent unit areas 304.

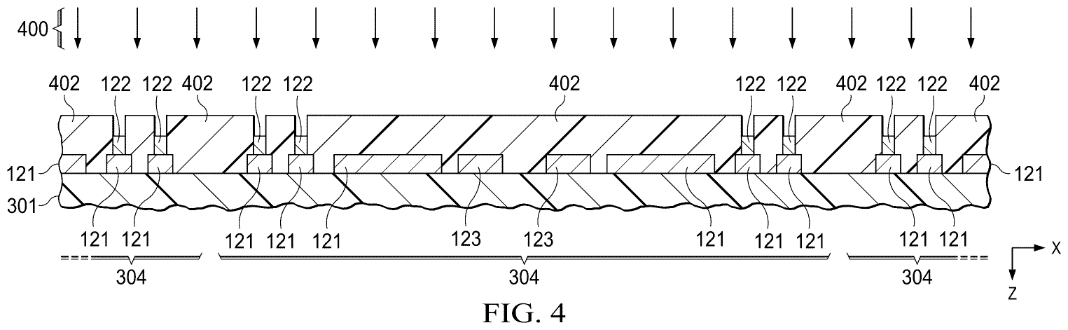

The method 200 continues at 204 in FIG. 2 with plating first conductive via features of the first level 141. FIG. 4 shows one example, with the first plating mask removed and a first via plating mask 402 is deposited and patterned. Another electroplating process 400 is performed that deposits further copper to form the first via layer including a first via features 122. Thereafter, the plating mask 402 is removed, and an etch process (not shown) is performed to remove the first copper seed layer between the electroplated first via and first trace features of the first level 141.

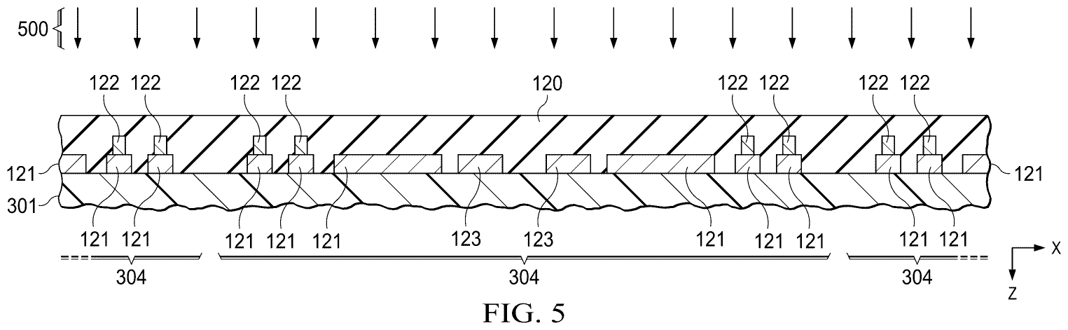

At 206 in FIG. 2, the method 200 continues with compression molding for the dielectric of the first level 141. FIG. 5 shows one example, in which a compression molding process 500 is performed that compression molds the first dielectric layer 120 of electrically insulating material between and over the patterned conductive trace and via features of the first level 141. In one example, the compression molded dielectric layer 120 of the first level 141 is or includes magnetic material, although not a requirement of all possible implementations, such as magnetic particles embedded in a sheet of compression moldable material 120 pressed onto the previously plated conductive trace and via features to fill in gaps there between.

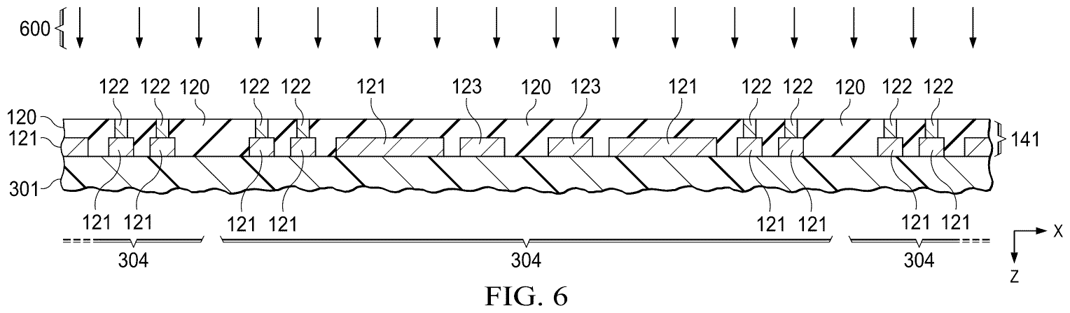

The method 200 continues at 208 with a grinding or other planarization process. FIG. 6 shows one example, in which a grinding process 600 is performed that grinds and planarizes the top side of the structure. The grinding process 600 removes an upper portion of the compression molded dielectric material 120 to expose upper portions of the conductive via features 122 of the first level as shown in FIG. 6. The grinding process 600 can be continued to reduce the thickness of the conductive copper and dielectric features of the first level 141 to a desired final thickness along the third direction Z as shown in FIG. 6. The processing at 202-208 in FIG. 2 forms the conductive U-shaped trace 123 in the top level 141 of the multilevel package substrate. A second copper seed layer (not shown) can then be deposited on the planarized top side of the first level 141 to be used in forming the second level 142 or any desired intermediate level beneath the first level 141.

In one implementation, one or more intermediate levels can be formed at 202 in FIG. 2 using similar processing to that described above at 202-208 in FIG. 2. In the illustrated example, the intermediate level formation at 210 is omitted, and the method 200 proceeds to 212 to begin forming the final or bottom level 142.

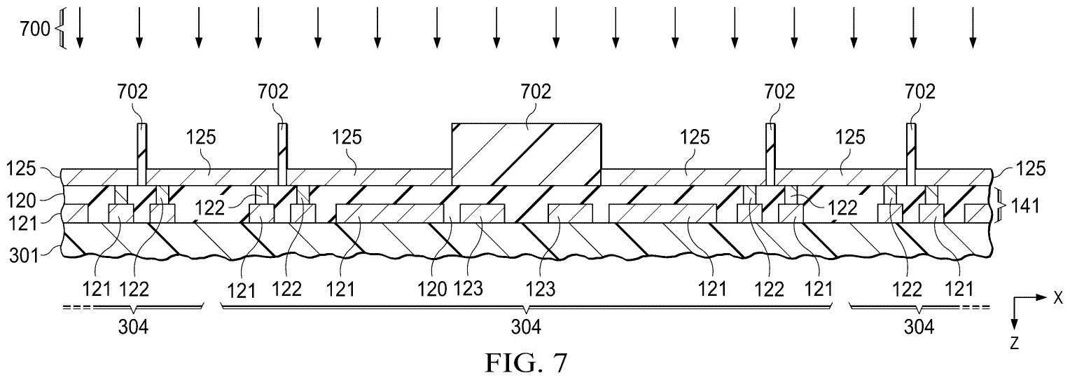

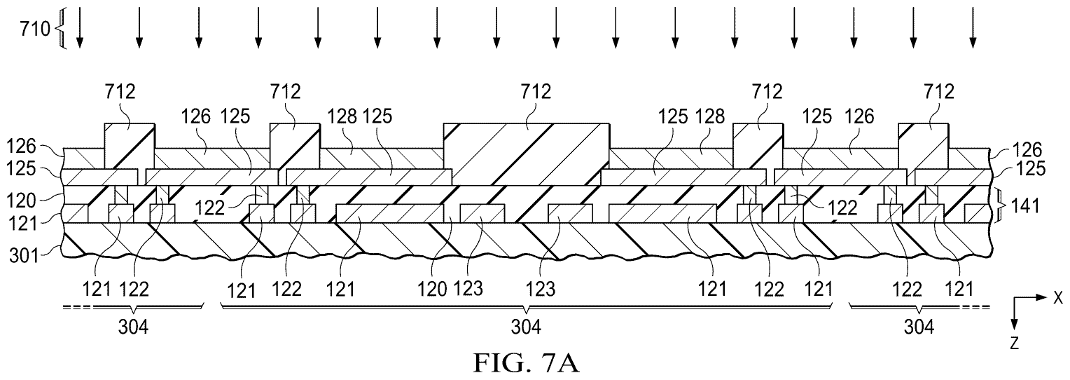

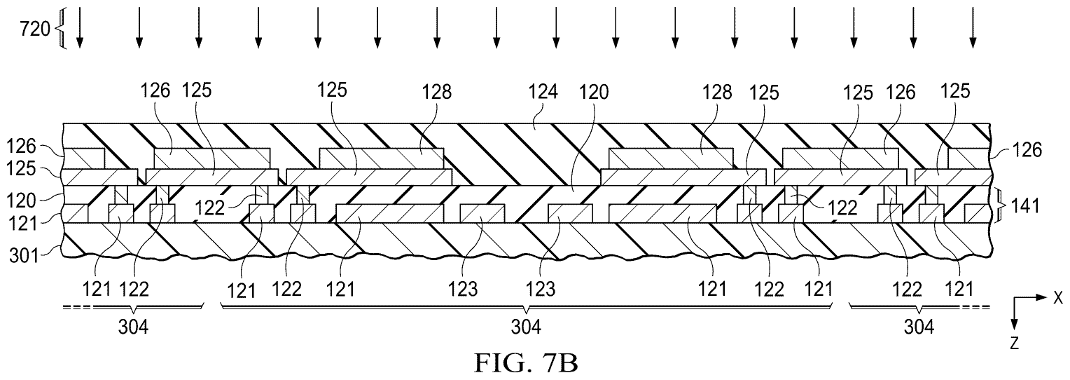

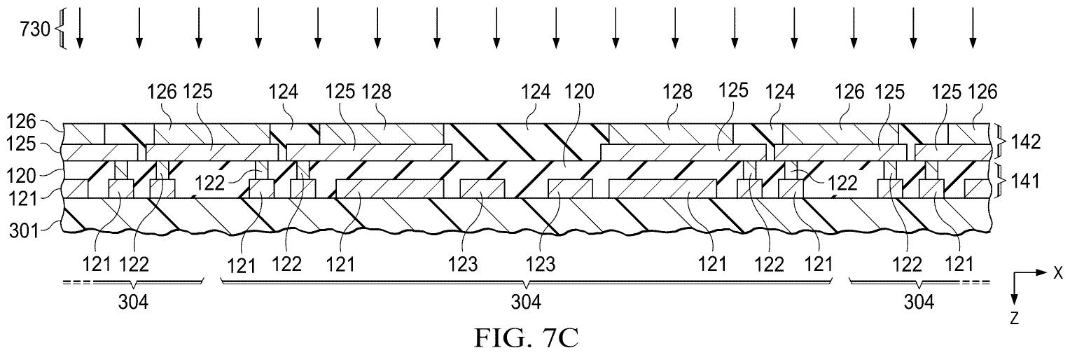

At 212, the method 200 continues with forming the above-described bottom level 142, including plating the conductive leads 126 and any included isolated split pads. FIGS. 7-7C show one example, in which an electroplating process 700 is performed with a second trace plating mask 702. The process 700 deposits copper in the exposed areas of the mask 702 to form the copper metal trace features of the second level 142 on the exposed portions of the second copper seed layer on the top side of the first level 141, including the top portions of the conductive leads 125 in the bottom level 142 of the multilevel package substrate.

The second trace plating mask 702 is then removed, and a second via plating mask 712 is formed as shown in FIG. 7A. Another electroplating process 710 is performed deposits copper in the exposed areas of the mask 712 to form the copper metal via features including the bottom or via portions of the leads 126 and the example conductive split pads 128 in the bottom level 142 of the multilevel package substrate. The bottom level formation continues in FIG. 7B with compression molding of the dielectric 124 of the second level 142. A compression molding process 720 is performed in FIG. 7B that compression molds the second dielectric layer 124 of electrically insulating material between and over the patterned conductive trace and via features of the second level 142. A grinding or other planarization process 730 is performed in FIG. 7C that grinds and planarizes the second level, for example, removing an upper portion of the compression molded dielectric material 124 to expose upper portions of the conductive via features 126 and the split pads 128 of the second level 142. The grinding process 730 can be continued to reduce the thickness of the conductive copper and dielectric features of the second level 142 to a desired final thickness along the third direction Z.

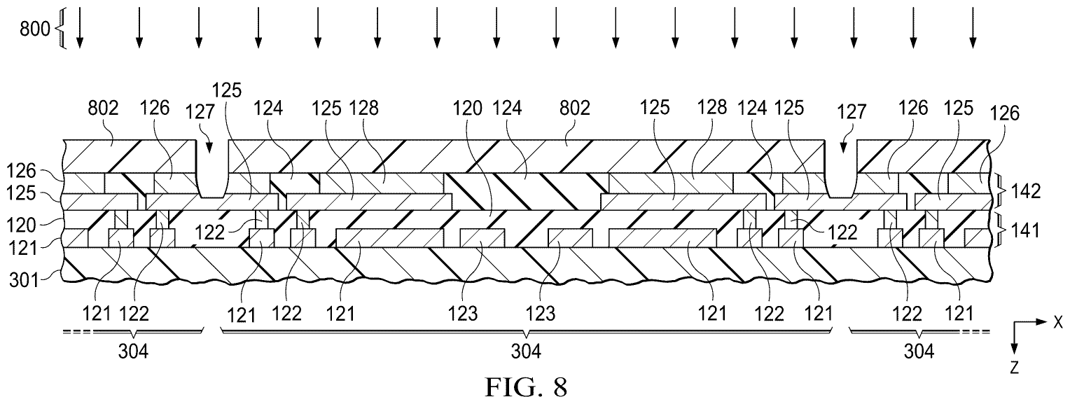

In one example, the method 200 continues at 214 with optional half etch processing. In another implementation, the half etching at 214 can be omitted. In the illustrated example, an etch process 800 is performed in FIG. 8 using an etch mask 802 that exposes prospective lead sides. The etch process 800 in this example forms the indents 127 in the prospective leads and includes etching portions of the second via and trace lead features 126 and 125, respectively as shown in FIG. 8, although not a requirement of all possible implementations. The etched portions form the indent 127 in lateral sides of adjacent unit areas 304 to form the indent 127 in the conductive leads 126 along the bottom side of the multilevel package substrate that forms the first side 101 of the finished electronic devices 100 in each unit area 304.

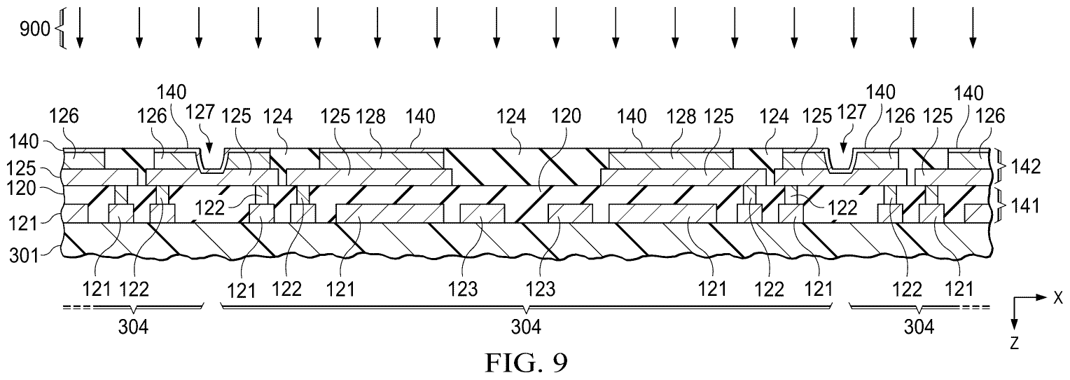

The method 200 continues at 216 in FIG. 2 in one example with optional plating of the leads and split pads in each unit area 304 of the panel array. FIG. 9 shows one example, in which a plating process 900 is performed that electroplates a plated surface 140 on the bottoms and etched indents of the conductive leads 126 in each unit area 304. The plating process 900 in one example also forms plated surfaces 140 on the bottom sides of the conductive split pads 128 in the bottom level 142 of the multilevel package substrate. In another implementation, the optional lead plating at 216 in FIG. 2 can be omitted.

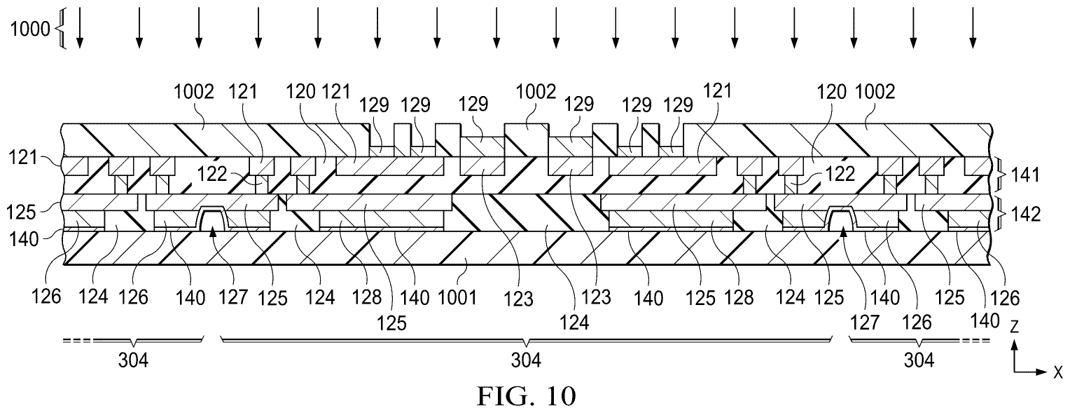

The method 200 in one example continues at 218 in FIG. 2 with forming raised studs 129 on the top level 141 of the multilevel package substrate 107. FIG. 10 shows one example, in which a masked electroplating process 1000 is performed using a plating mask 1002 that exposes select portions of the first conductive metal trace features 121 of the first level 141. In this example, instances of the raised studs 129 can be formed on top of the U-shaped trace 123 in each unit area 304. In another implementation, no raised studs 129 are formed over the top of the U-shaped trace 123, for example, to facilitate filling of the space between the ultimately attached semiconductor die 110 and the U-shaped trace 123 with magnetic molded compound of the package structure 108. In another implementation, the stud formation at 218 in FIG. 2 can be omitted. The raised studs 129 in the illustrated example provide a standoff to raise the bottom side of the semiconductor die 110 relative to the top side of the first level 141, for example, to facilitate magnetic mold compound underfill beneath the semiconductor die 110 in the finished electronic device 100.

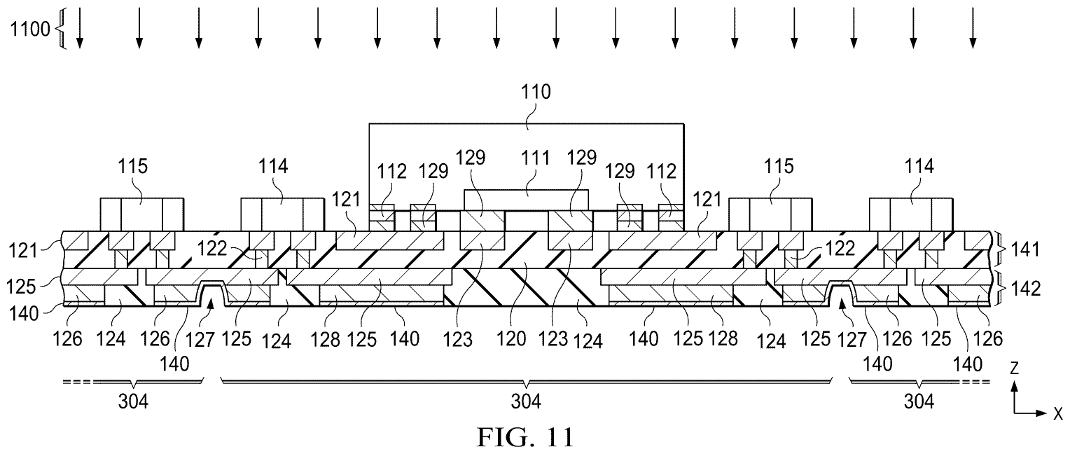

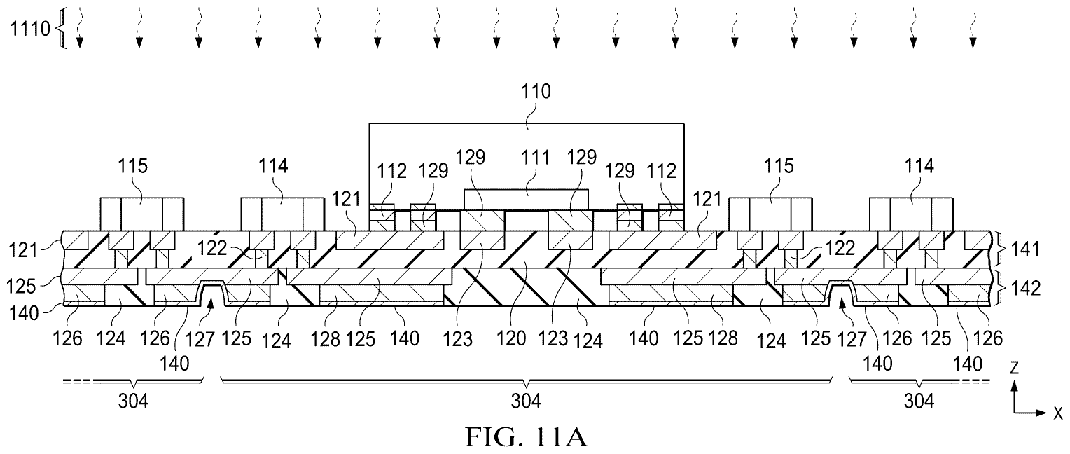

At 220 in FIG. 2, a semiconductor die and any included other components 114-117 are attached in each unit area 304 of the panel array structure. FIG. 11 shows one example, in which an attachment process 1100 is performed that attaches the semiconductor die 110 to the top level 141 of the multilevel package substrate 107 with a Hall sensor 111 positioned above the U-shaped trace 123. In this example, moreover, surface mount components (e.g., resistors, capacitors, etc.) 114-117 are also attached in each unit area 304 of the panel array structure. The attachment processing 1100 can include an initial formation of solder paste along the top sides of the first conductive trace features 121 and/or over any provided raised studs 129 to which a component or a terminal of a component is to be attached. Any suitable solder paste formation technique and equipment can be used, for example, dispensing, printing, silk screening, etc. The components 114-117 and the semiconductor die 110 are then placed in appropriate locations, for example, using automated pick and place equipment (not shown) to engage conductive metal terminals of the components 114-117 and the terminals 112 of the semiconductor die 110 to the previously formed solder paste in each unit area 304. The attach processing 1100 in one example also includes a solder reflowing process 1110 in FIG. 11A, such as a thermal reflow process to create solder joints between the terminals of the semiconductor die 110 and the components 114-117 and the corresponding trace features 121 or raised studs 129 of the multilevel package substrate 107.

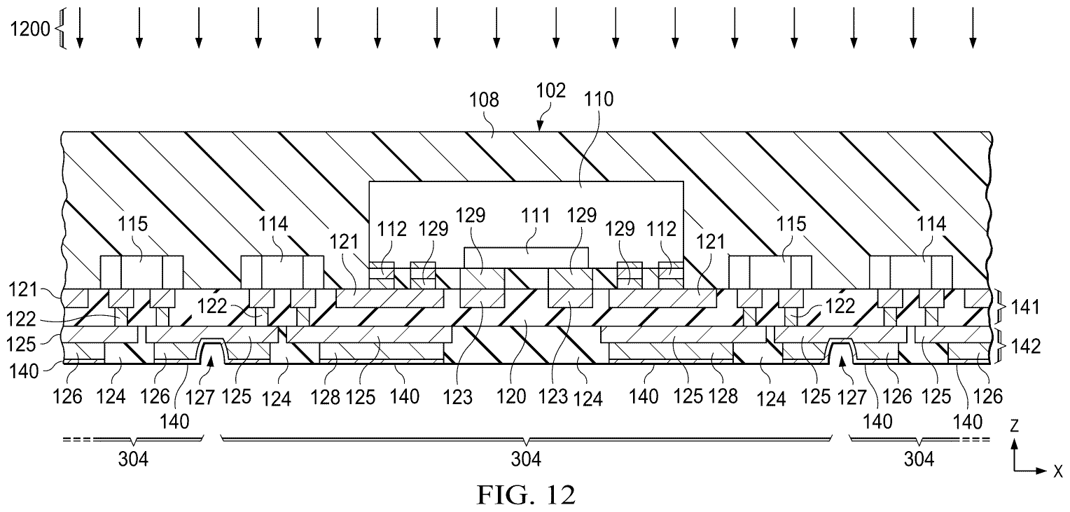

The method 200 continues at 222 in FIG. 2 with molding processing to form the molded package structure 108. FIG. 12 shows one example, in which a molding process 1200 is performed to form the molded package structure 108 that encloses at least a portion of the U-shaped trace 123 or of any included race stud 129 connected to the U-shaped trace 123. In one example, the molding process 1200 incorporates a magnetic material in the package structure 108, for example, using magnetic mold compound. In one example, a single mold cavity can be used to form a unitary magnetic molded structure 108 that extends across all the rows and columns of the panel array structure. In another implementation, individual mold cavities can be used to form respective molded magnetic package structures 108 in each unit area 304. In other implementations, the individual mold cavities can extend across two or more unit areas 304 of the array structure, for example, to form magnetic molded package structures 108 along rows or columns of the array structure. The molding process 1200 in one example molds the magnetic package structure 108 to enclose a portion of the semiconductor die 110 and a top side of the multilevel package substrate in each unit area 304.

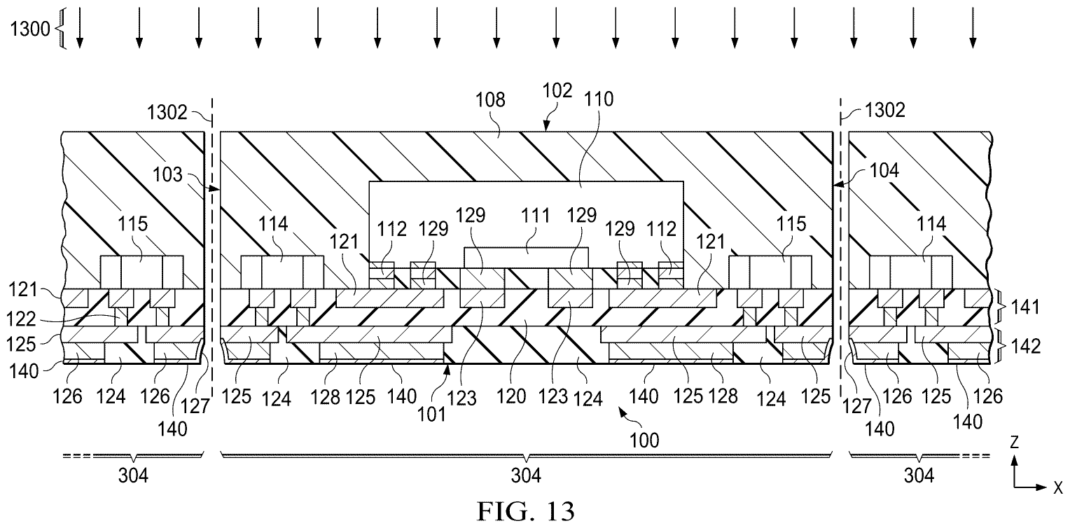

The method 200 also includes package separation at 224 in FIG. 2. FIG. 13 shows one example, in which a saw cutting or laser cutting process 1300 is performed that separates individual finished packaged electronic devices 100 from a concurrently processed panel or array structure along lines 1302. Any suitable package separation process 1300 can be used, for example, saw cutting, laser cutting, chemical etching, etc., or combinations thereof.

Modifications are possible in the described examples, and other implementations are possible, within the scope of the claims.

What is claimed is:

1. An electronic device, comprising:
a multilevel package substrate having a top level and a bottom level, the top level including a conductive U-shaped trace, the bottom level including a conductive lead exposed along a side of the electronic device;
a semiconductor die attached to the top level of the multilevel package substrate and having a Hall sensor positioned above the U-shaped trace; and
a package structure that encloses a portion of the semiconductor die and a portion of the U-shaped trace.

2. The electronic device of claim 1, further comprising a surface mount component with terminals soldered to pads of the top level of the multilevel package substrate.

3. The electronic device of claim 1, wherein the bottom level includes conductive split pads spaced apart from the conductive lead and exposed along the side of the electronic device.

4. The electronic device of claim 1, wherein the conductive lead has an indent along the side of the electronic device.

5. The electronic device of claim 1, wherein the conductive lead has a plated surface exposed along the side of the electronic device.

6. The electronic device of claim 1, wherein the package structure includes a magnetic material.

7. The electronic device of claim 6, wherein the multilevel package substrate includes a magnetic material.

8. The electronic device of claim 1, wherein the multilevel package substrate includes a magnetic material.

9. A system, comprising:
a circuit board having a conductive trace; and
an electronic device, comprising:
a multilevel package substrate having a top level and a bottom level, the top level including a conductive U-shaped trace, the bottom level including a conductive lead exposed along a side of the electronic device and attached to the conductive trace;
a semiconductor die attached to the top level of the multilevel package substrate and having a Hall sensor positioned above the U-shaped trace; and
a package structure that encloses a portion of the semiconductor die and a portion of the U-shaped trace.

10. The system of claim 9, wherein the electronic device further comprises a surface mount component with terminals soldered to pads of the top level of the multilevel package substrate.

11. The system of claim 9, wherein the bottom level includes conductive split pads spaced apart from the conductive lead and exposed along the side of the electronic device.

12. The system of claim 9, wherein the package structure includes a magnetic material.

13. The system of claim 9, wherein the multilevel package substrate includes a magnetic material.

14. A method of fabricating an electronic device, the method comprising:
forming a conductive U-shaped trace in a top level of a multilevel package substrate;
forming a conductive lead in a bottom level of the multilevel package substrate;
attaching a semiconductor die to the top level of the multilevel package substrate with a Hall sensor positioned above the U-shaped trace; and
molding a package structure that encloses the U-shaped trace.

15. The method of claim 14, further comprising:
forming pads in the top level of the multilevel package substrate; and
attaching a surface mount component to the top level of the multilevel package substrate with terminals soldered to the pads.

16. The method of claim 14, further comprising forming raised studs on the top level of the multilevel package substrate.

17. The method of claim 14, comprising forming conductive split pads in the bottom level of the multilevel package substrate.

18. The method of claim 14, further comprising forming an indent in the conductive lead along the side of the electronic device.

19. The method of claim 14, further comprising forming a plated surface on the conductive lead.

20. The method of claim 14, comprising incorporating a magnetic material in the multilevel package substrate or the package structure.
